(19) United States
(12) Patent Application Publication
(10) Pub. No.: US 2024/0290613 A1
(43) Pub. Date: Aug. 29, 2024

(54) WAFER PROCESSING METHOD

(71) Applicant: DISCO CORPORATION, Tokyo (JP)

(72) Inventor: Naoki KITA, Tokyo (JP)

(21) Appl. No.: 18/436,272

(22) Filed: Feb. 8, 2024

(30) Foreign Application Priority Data
Feb. 28, 2023 (JP) 2023-030229

(51) Int. Cl. H01L 21/02

(52) U.S. Cl. CPC H01L 21/02354

(57) ABSTRACT

A wafer processing method includes a circular recess forming step of forming a circular recess in a center of a back surface of a wafer to thereby form an annular projection surrounding the circular recess, and a modified layer forming step of applying a laser beam of such a wavelength as to be transmitted through the wafer to the annular projection to thereby form a modified layer.

### BACKGROUND OF THE INVENTION

### Field of the Invention

The present invention relates to a wafer processing method.

### Description of the Related Art

For example, to facilitate handling of a wafer after thinning the wafer, there has been used a processing method in which a center of a back surface of the wafer is ground to form a circular recess and to form a peripheral projection surrounding the circular recess (see, for example, Japanese Patent Laid-open No. 2007-19461).

The wafer formed with the circular recess by the processing method disclosed in Japanese Patent Laid-open No. 2007-19461 is subjected to formation of a metallic film on the back surface of the wafer, after which the wafer is divided into individual devices.

### SUMMARY OF THE INVENTION

However, when the wafer is ground to thin the wafer to, for example, a thickness of 100 μm or below, the wafer at a part corresponding to the circular recess may be deflected. If the wafer is deflected, it would become difficult to accommodate the wafer in a cassette, and the risk of breakage of the wafer would be enhanced, so that improvement has been desired earnestly.

Accordingly, it is an object of the present invention to provide a wafer processing method by which deflection of a wafer formed with a circular recess can be suppressed.

In accordance with an aspect of the present invention, there is provided a wafer processing method including a circular recess forming step of forming a circular recess in a center of a back surface of a wafer to thereby form an annular projection surrounding the circular recess, and a modified layer forming step of applying a laser beam of such a wavelength as to be transmitted through the wafer to the annular projection to thereby form a modified layer, before or after carrying out the circular recess forming step.

Preferably, the modified layer forming step is carried out before carrying out the circular recess forming step.

The present invention produces an effect that deflection of the wafer formed with the circular recess can be suppressed.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically depicting a wafer to be processed by a wafer processing method according to an embodiment of the present invention;

FIG. 2 is a flow chart depicting a flow of the wafer processing method according to the embodiment;

FIG. 3 is a perspective view schematically depicting a tape sticking step of the wafer processing method depicted in FIG. 2;

FIG. 4 is a sectional view schematically depicting a state in which the wafer is held under suction by a laser processing apparatus, in a modified layer forming step of the wafer processing method depicted in FIG. 2;

FIG. 5 is a sectional view schematically depicting a state in which a modified layer is formed in the wafer by the laser processing apparatus, in the modified layer forming step of the wafer processing method depicted in FIG. 2;

FIG. 6 is a plan view schematically depicting the wafer formed with the modified layer in the modified layer forming step of the wafer processing method depicted in FIG. 2;

FIG. 7 is a sectional view schematically depicting the wafer formed with the modified layer in the modified layer forming step of the wafer processing method depicted in FIG. 2;

FIG. 8 is a sectional view schematically depicting a state in which a center of a back surface of the wafer is subjected to rough grinding in a circular recess forming step of the wafer processing method depicted in FIG. 2;

FIG. 9 is a sectional view schematically depicting a state in which a bottom of a circular recess formed by the rough grinding of the back surface of the wafer is subjected to finish grinding in the circular recess forming step of the wafer processing method depicted in FIG. 2;

FIG. 10 is a sectional view schematically depicting the wafer obtained after the circular recess forming step of the wafer processing method depicted in FIG. 2; and

FIG. 11 is a flow chart depicting a modification of the wafer processing method depicted in FIG. 2.

### DETAILED DESCRIPTION OF THE PREFERRED EMBODIMENT

An embodiment of the present invention will be described in detail below with reference to the drawings. The present invention is not to be limited by the contents of the description of the following embodiment. In addition, the constituent elements described below include those which can easily be conceived by a person skilled in the art and those which are substantially the same. Further, the configurations described below can be combined with one another as required. Besides, various omissions, replacements, or modifications of the configurations are possible within such ranges as not to depart from the gist of the present invention.

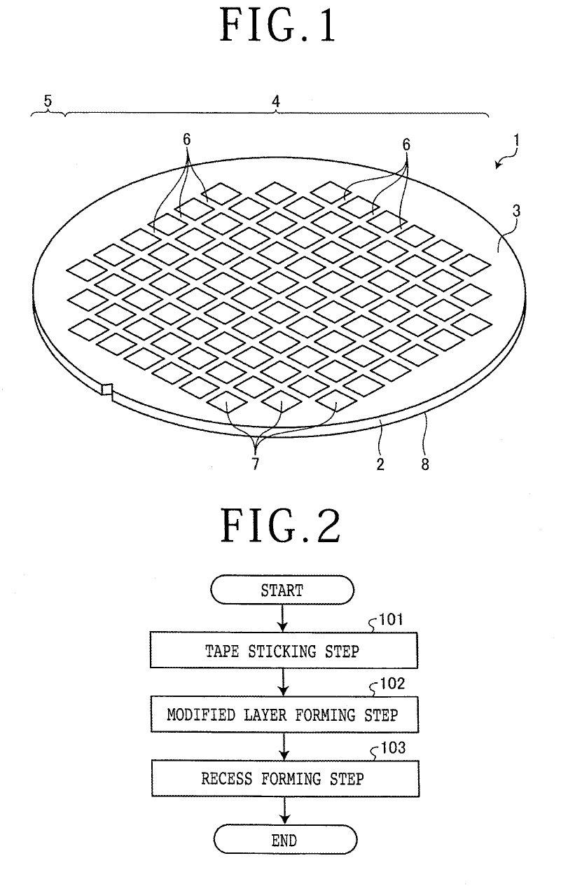

A wafer processing method according to the embodiment of the present invention will be described with reference to the drawings. FIG. 1 is a perspective view schematically depicting a wafer to be processed by the wafer processing method according to the embodiment. FIG. 2 is a flow chart depicting a flow of the wafer processing method according to the embodiment.

The wafer processing method according to the embodiment is a processing method for processing a wafer 1 depicted in FIG. 1. The wafer 1 to be processed by the wafer processing method according to the embodiment is a wafer such as a disk-shaped semiconductor wafer or optical device wafer formed of silicon, sapphire, gallium, or the like, as a substrate 2. As depicted in FIG. 1, the wafer 1 includes a device region 4 and a peripheral surplus region 5 surrounding the device region 4, in a front surface 3 of the substrate 2.

The device region 4 has streets 6 set in a grid pattern on the front surface 3 of the substrate 2, and devices 7 formed in the respective regions partitioned by the streets 6.

The device 7 is, for example, an integrated circuit (IC) device such as an IC and a large-scale integration (LSI), an image sensor such as a charge coupled device (CCD) and a complementary metal oxide semiconductor (CMOS), or micro electro mechanical systems (MEMS) or a semiconductor memory (semiconductor storage device). The peripheral surplus region 5 is a region which surrounds the device region 4 over the whole circumference and in which the devices 7 are not formed on the front surface 3 of the substrate 2. Note that, in the embodiment, the wafer 1 has an outside diameter of 300 mm.

Next, the wafer processing method according to the embodiment will be described. The wafer processing method according to the embodiment is a processing method for processing the wafer 1. As depicted in FIG. 2, the wafer processing method according to the embodiment includes a tape sticking step 101, a modified layer forming step 102, and a circular recess forming step 103.

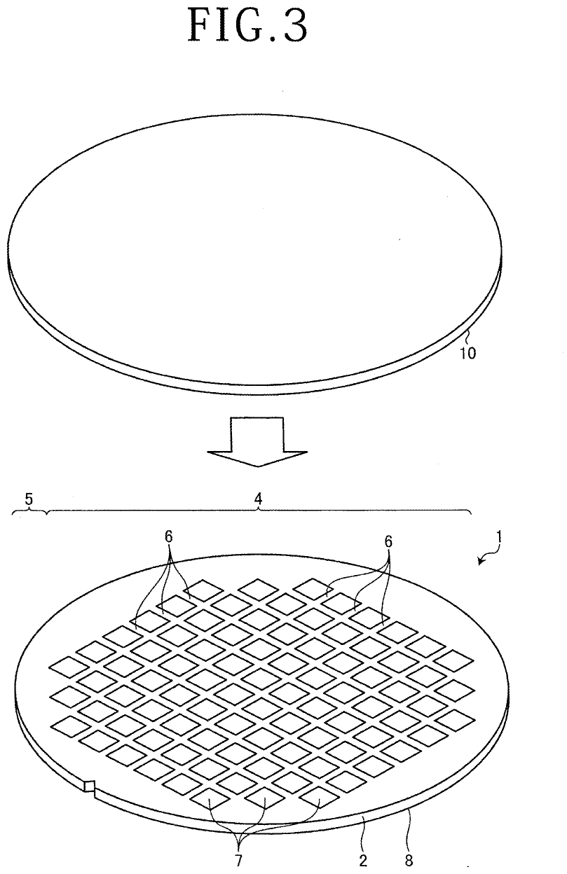

FIG. 3 is a perspective view schematically depicting the tape sticking step of the wafer processing method depicted in FIG. 2. The tape sticking step 101 is a step of sticking a tape 10 to the front surface 3 of the wafer 1.

In the embodiment, the tape 10 is an adhesive tape including a base material layer that is formed in a disk-like shape having the same diameter as the wafer 1 and is formed of resin having a non-sticky property and flexibility, and a glue layer that is laminated on the base material layer and is formed of resin having a sticky property and flexibility, the glue layer being stuck to the front surface 3 of the wafer 1. Alternatively, the tape 10 is a sheet having no glue layer and including only a base material layer that is formed of a thermoplastic resin, and being stuck to the front surface 3 of the wafer 1 by thermocompression adhesion. In the embodiment, in the tape sticking step 101, as depicted in FIG. 3, the tape 10 is made to face the front surface 3 of the wafer 1, and thereafter the tape 10 is stuck to the front surface 3 of the wafer 1.

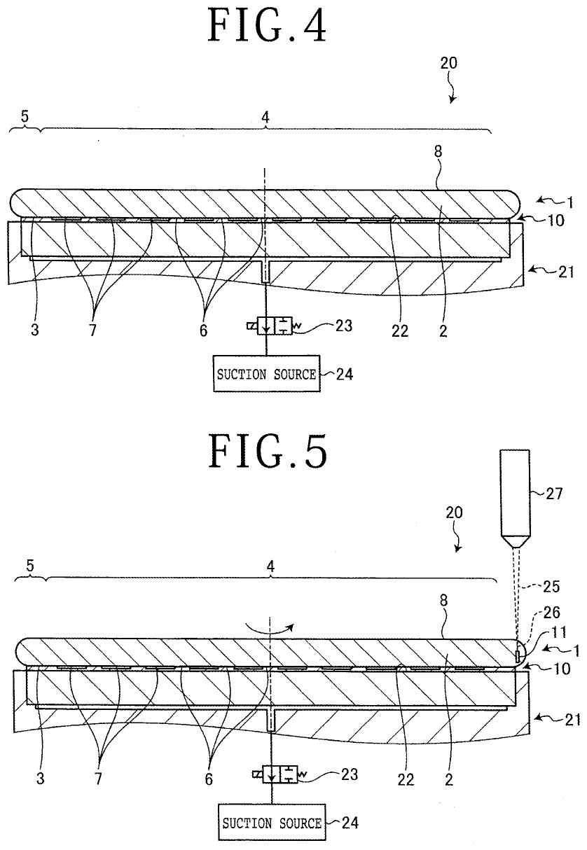

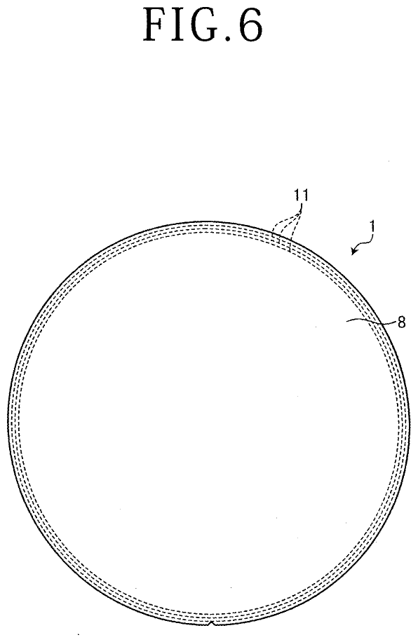

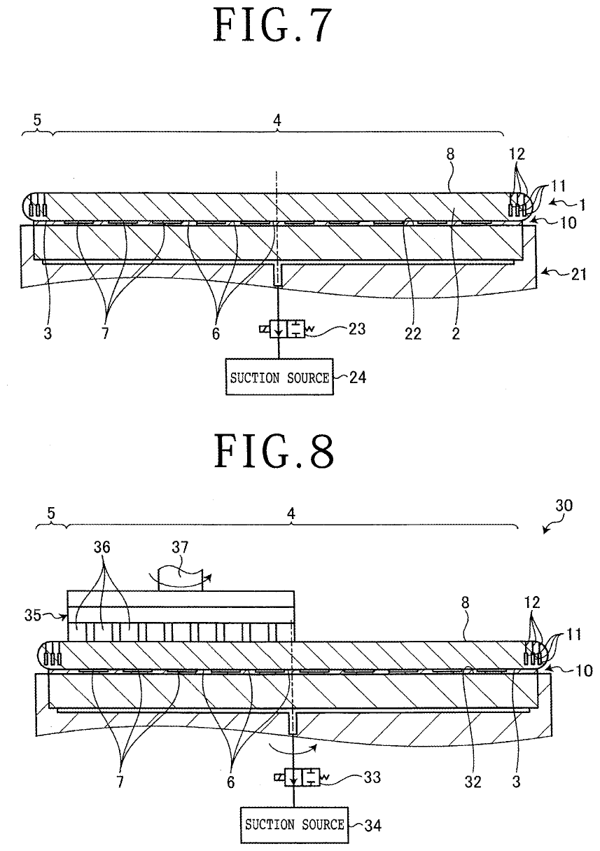

FIG. 4 is a sectional view schematically depicting a state in which the wafer is held under suction by a laser processing apparatus, in the modified layer forming step of the wafer processing method depicted in FIG. 2. FIG. 5 is a sectional view schematically depicting a state in which a modified layer is formed in the wafer by the laser processing apparatus, in the modified layer forming step of the wafer processing method depicted in FIG. 2. FIG. 6 is a plan view schematically depicting the wafer formed with the modified layer in the modified layer forming step of the wafer processing method depicted in FIG. 2. FIG. 7 is a sectional view schematically depicting the wafer formed with the modified layer in the modified layer forming step of the wafer processing method depicted in FIG. 2.

The modified layer forming step 102 is a step of applying a laser beam 25 of such a wavelength as to be transmitted through the wafer 1 to an annular projection 14 (depicted in FIG. 10) to be formed in the circular recess forming step 103, to thereby form a modified layer 11, before carrying out the circular recess forming step 103. As such, in the wafer processing method according to the embodiment, the modified layer forming step 102 is carried out before carrying out the circular recess forming step 103. In the modified layer forming step 102, in the laser processing apparatus 20, as depicted in FIG. 4, the front surface 3 side of the wafer 1 is mounted on a holding surface 22 of a chuck table 21 with the tape 10 therebetween, and an on-off valve 23 is opened to cause the holding surface 22 to be sucked by a suction source 24, whereby the front surface 3 side of the wafer 1 is held under suction by the holding surface 22.

In the modified layer forming step 102, the laser processing apparatus 20 is operated such that, as depicted in FIG. 5, a focal point 26 of the laser beam 25 of such a wavelength as to be transmitted through the wafer 1 is positioned in the inside of the peripheral surplus region 5 of the wafer 1, and while the chuck table 21 is rotated around an axis orthogonal to the holding surface 22, thereby moving the wafer 1 and a laser beam applying unit 27 relative to each other along an outer edge of the wafer 1, the pulsed laser beam 25 is applied to the peripheral surplus region 5 of the wafer 1 along the outer edge of the wafer 1 from a back surface 8 side of the wafer 1.

As a result, since the wavelength of the laser beam 25 is such a wavelength as to be transmitted through the wafer 1, as depicted in FIGS. 6 and 7, the modified layer 11 is formed in the inside of the peripheral surplus region 5 of the wafer 1 along the outer edge of the wafer 1 over the whole circumference. Note that the modified layer 11 represents a region different in density, refractive index, mechanical strength, or other physical properties from those of the surroundings, and examples of such a region include a melting treatment region, a cracked region, a dielectric breakdown region, a refractive index variation region, and a region in which these regions are present in a mixed manner. Note that the mechanical strength of the modified layer 11 is lower than the mechanical strengths of those parts of the wafer 1 which are other than the modified layer 11.

In addition, in the embodiment, in the modified layer forming step 102, the laser beam 25 is applied to the peripheral surplus region 5 along the outer edge of the wafer 1, with the focal point 26 being positioned at a position at which a crack 12 (depicted in FIG. 7) extending from the modified layer 11 is exposed at the back surface 8 of the peripheral surplus region 5 of the wafer 1 and being positioned at a position closer to the front surface 3 side than a half of the thickness of the wafer 1. Besides, in the embodiment, in the modified layer forming step 102, three modified layers 11 are formed in the peripheral surplus region 5 of the wafer 1 at intervals in the radial direction.

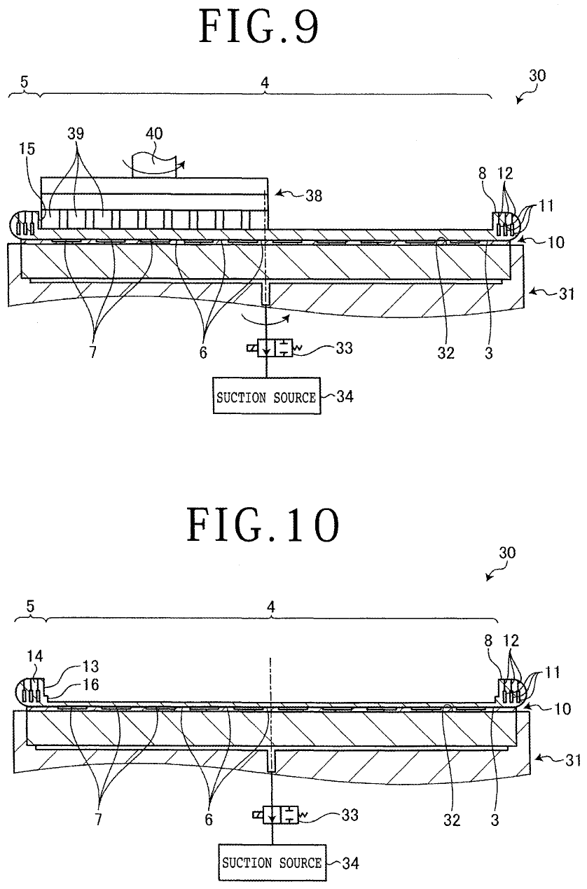

FIG. 8 is a sectional view schematically depicting a state in which a center of the back surface of the wafer is subjected to rough grinding in the circular recess forming step of the wafer processing method depicted in FIG. 2. FIG. 9 is a sectional view schematically depicting a state in which a bottom of the circular recess formed by the rough grinding in the back surface of the wafer in the circular recess forming step of the wafer processing method depicted in FIG. 2 is subjected to finish grinding. FIG. 10 is a sectional view schematically depicting the wafer obtained after the circular recess forming step of the wafer processing method depicted in FIG. 2.

The circular recess forming step 103 is a step of forming the circular recess 13 (depicted in FIG. 10 and corresponding to the circular recess) in the center of the back surface 8 of the wafer 1 to thereby form the annular projection 14 (depicted in FIG. 10) surrounding the circular recess 13. In the embodiment, the circular recess forming step 103 is a step of what is generally called TAIKO (registered trademark) grinding in which the circular recess 13 (corresponding to the circular recess) is formed in the back surface 8 of the device region 4 to thereby form the peripheral surplus region 5 at the annular projection 14 (corresponding to the projection) which is thicker than the device region 4.

In the embodiment, in the circular recess forming step 103, a grinding apparatus 30 is operated such that the front surface 3 side of the wafer 1 is mounted on a holding surface 32 of a chuck table 31 with the tape 10 therebetween and an on-off valve 33 is opened to cause the holding surface 32 to be sucked by a suction source 34, whereby the front surface 3 side of the wafer 1 is held under suction on the holding surface 32. In the embodiment, in the circular recess forming step 103, the grinding apparatus 30 is operated such that, as depicted in FIG. 8, a grinding wheel 35 for rough grinding is rotated around an axis by a spindle 37 and the chuck table 31 is rotated around an axis, and, while a grinding liquid is supplied from a grinding liquid nozzle, grindstones 36 for rough grinding of the grinding wheel 35 are brought into contact with at least the back surface 8 of the device region 4 of the wafer 1 and are brought closer to the chuck table 31 at a predetermined feeding rate, whereby the back surface 8 of the device region 4 of the wafer 1 is subjected to rough grinding by the grindstones 36.

Note that, in the embodiment, the outside diameter of the grinding wheel 35 is smaller than the radius of the wafer 1 and roughly equivalent to the radius of the device region 4 (in the embodiment, equal to the radius of the device region 4). In addition, in the embodiment, in the circular recess forming step 103, the grinding apparatus 30 causes the grindstones 36 for rough grinding of the grinding wheel 35 to be brought into contact with the back surface 8 of the device region 4 in such a manner as to pass through the center of the wafer 1, thereby subjecting the back surface 8 to rough grinding and forming a circular recess 15 in the back surface 8 of the device region 4.

In the embodiment, in the circular recess forming step 103, the grinding apparatus 30 is operated to bring the grinding wheel 35 away from the back surface 8 of the wafer 1 when the thickness of the device region 4 of the wafer 1 has become a predetermined thickness. In the embodiment, in the circular recess forming step 103, the grinding apparatus 30 is operated such that, as depicted in FIG. 9, a grinding wheel 38 for finish grinding is rotated around an axis by a spindle 40 and the chuck table 31 is rotated around an axis, and, while the grinding liquid is supplied from the grinding liquid nozzle, grindstones 39 for finish grinding of the grinding wheel 38 are brought into contact with the bottom of the circular recess 15 formed in the back surface 8 of the device region 4 of the wafer 1 and are brought closer to the chuck table 31 at a predetermined feeding rate, whereby the bottom of the circular recess 15 formed in the back surface 8 of the device region 4 of the wafer 1 is subjected to finish grinding by the grindstones 39.

Note that, in the embodiment, the outside diameter of the grinding wheel 38 is smaller than the radius of the wafer 1 and is roughly equivalent to the radius of the device region 4 (in the embodiment, equal to the radius of the device region 4). In addition, in the embodiment, in the circular recess forming step 103, the grinding apparatus 30 is operated such that the grindstones 39 pass though the center of the wafer 1, the grinding wheel 38 for finish grinding is positioned at a position closer to the inner circumference side of the wafer 1 than the grinding wheel 35 for rough grinding, and the bottom of the circular recess 15 is subjected to finish grinding by the grinding wheel 38 for finish grinding, to thereby form the circular recess 13.

In the embodiment, in the circular recess forming step 103, the grinding apparatus 30 is operated to bring the grinding wheel 38 away from the back surface 8 of the wafer 1 when the thickness of the device region 4 of the wafer 1 has become a predetermined thickness (for example, more than 0 μm and equal to or less than 10 μm, and, in the embodiment, 10 μm). In this way, in the embodiment, in the circular recess forming step 103, the grinding apparatus 30 is operated in such a manner as to form the circular recess 13 in the center of the back surface 8 of the wafer 1, namely, in the back surface 8 of the device region 4, and to form the annular projection 14 surrounding the circular recess 13, as depicted in FIG. 10.

The circular recess 13 is formed in the region of the back surface 8 which overlaps with the device region 4 in the thickness direction, whereas the annular projection 14 is formed in the region of the back surface 8 which overlaps with the peripheral surplus region 5 in the thickness direction. For this reason, in the modified layer forming step 102, the laser beam 25 is applied to the annular projection 14 to thereby form the modified layer 11 in the annular projection 14.

Thus, the back surface 8 of the wafer 1 obtained after the circular recess forming step 103 is carried out has the circular recess 13 formed in the center thereof and the annular projection 14 surrounding the circular recess 13, whereby a step is formed between the device region 4 and the peripheral surplus region 5. In addition, the front surface 3 of the wafer 1 is formed to be flush with the whole range of the device region 4 and the peripheral surplus region 5. Note that the bottom surface of the circular recess 13 is a ground surface having undergone grinding or the like by the grinding apparatus. Besides, in the embodiment, as depicted in FIG. 10, the bottom surface of the circular recess is formed with a step 16 which is coaxial with the wafer 1.

The wafer 1 thus formed with the circular recess 13 is subjected to formation of a metallic film on the bottom surface of the circular recess 13, after which the wafer 1 is divided into the individual devices 7.

As has been described above, in the wafer processing method according to the embodiment, the modified layer 11 is formed in the annular projection 14 in the modified layer forming step 102, whereby the annular projection 14 is expanded, so that the deflection of the wafer 1, particularly, of the circular recess 13, obtained after the circular recess forming step 103 is carried out, can be eliminated. In addition, in the wafer processing method according to the embodiment, the modified layer 11 is formed in the annular projection 14 along the outer edge of the wafer 1 in the modified layer forming step 102, and, hence, the annular projection 14 is expanded in the radial direction of the wafer 1, so that a stress for shrinkage in the radial direction acts on the circular recess 13.

As a result, the wafer processing method according to the embodiment produces an effect that the deflection of the wafer 1, particularly, of the circular recess 13, obtained after the circular recess forming step 10 is carried out, can be suppressed, and the deflection of the wafer 1 formed with the circular recess 13 can be suppressed.

In addition, in the wafer processing method according to the embodiment, since the modified layer forming step 102 is carried out before carrying out the circular recess forming step 103, a stress for shrinkage in the radial direction can be made to act on the device region 4 of the wafer 1 before the circular recess 13 is formed in the wafer 1, so that deflection can be suppressed even when the circular recess 13 is formed in the circular recess forming step 103, conveyance of the wafer 1 is facilitated, and the risk of breakage of the wafer 1 can be suppressed.

Next, the inventor of the present invention confirmed the effect of the wafer processing method according to the embodiment. The results are set forth in Table 1. The product of the present invention in Table 1 indicates the result of measurement of a positional deviation of the center and the outer edge of the wafer 1 in the axial direction as deflection, in a case where the wafer 1 having an outside diameter of 300 mm and a thickness of 775 μm was subjected to the wafer processing method according to the embodiment, to reduce the thickness of the circular recess 13 to 80 μm, and only the annular projection 14 of the wafer 1 was supported. The comparative example in Table 1 indicates the result of measurement of a positional deviation of the center and the outer edge of the wafer 1 in the axial direction as deflection, in the case where the wafer 1 having an outside diameter of 300 mm and a thickness of 775 μm was subjected only to the circular recess forming step 103 without carrying out the modified layer forming step 102 to reduce the thickness of the circular recess 13 to 80 μm, and only the annular projection 14 of the wafer 1 was supported.

TABLE 1

| | Deflection |
|---|---|
| Product of Present Invention | 347 μm |
| Comparative Example | 410 μm |

According to Table 1, while the deflection in Comparative Example is 410 μm, the deflection of the product of the present invention is 347 μm, thereby achieving suppression of the deflection by 63 μm (15%) by carrying out the wafer processing method according to the embodiment. Hence, according to Table 1, it has become clear that the deflection of the wafer 1 formed with the circular recess 13 can be suppressed by formation of the modified layer 11 in the annular projection 14 in the modified layer forming step 102.

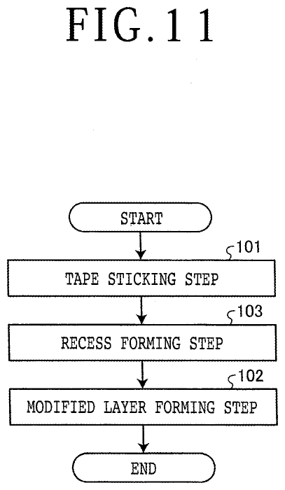

Note that the present invention is not to be limited to the above-described embodiment. In other words, the present invention can be carried out with various modifications within such ranges as not to depart from the gist of the invention. For example, the present invention may be carried out by performing the modified layer forming step 102 after performing the circular recess forming step 103, as depicted in FIG. 11. Note that FIG. 11 is a flow chart depicting a modification of the wafer processing method depicted in FIG. 2. In FIG. 11, the same parts as those in the embodiment described above are denoted by the same reference numerals as those used above, and descriptions thereof are omitted.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A wafer processing method comprising:
a circular recess forming step of forming a circular recess in a center of a back surface of a wafer to thereby form an annular projection surrounding the circular recess; and
a modified layer forming step of applying a laser beam of such a wavelength as to be transmitted through the wafer to the annular projection to thereby form a modified layer, before or after carrying out the circular recess forming step.

2. The wafer processing method according to claim 1,
wherein the modified layer forming step is carried out before carrying out the circular recess forming step.
